(19) United States
(12) Patent Application Publication
(10) Pub. No.: US 2014/0125371 A1
(43) Pub. Date: May 8, 2014

(54) STAND ALONE MULTI-CELL PROBE CARD FOR AT-SPEED FUNCTIONAL TESTING

(71) Applicant: Hermes Testing Solutions Inc., Hsinchu City (TW)

(72) Inventors: MENG-HSIU CHUNG, Kaohsiung City (TW); Hung-Wei Lai, Kaohsiung City (TW)

(73) Assignee: HERMES TESTING SOLUTIONS INC., Hsinchu City (TW)

(21) Appl. No.: 14/058,217

(22) Filed: Oct. 19, 2013

Related U.S. Application Data
(60) Provisional application No. 61/722,639, filed on Nov. 5, 2012.

(51) Int. Cl. G01R 1/04

(52) U.S. Cl. CPC G01R 1/0433
USPC 324/756.03

(57) ABSTRACT

A probe card includes at least two connection arrangements on a printed circuit board and a daughter board connected to the printed circuit board through one of the connection arrangements. The daughter board includes a plurality of cell modules, with each of the cell modules having a socket for receiving a device under test and each of the connection arrangements of the printed circuit board being connectable to each of predetermined daughter boards respectively.

### BACKGROUND OF THE INVENTION

1. Field of the Invention

The present invention relates to a semiconductor device testing at wafer level stage, and more particular to a method and an apparatus of stand along muti-cell probe card with high speed testing capability.

2. Description of the Prior Art

The conventional semiconductor testing requires a system consisted of ATE (Auto Test Equipment) and probers or handlers. The signal traveling paths from ATE/test head to PIB (Probe Interface Board) or Load board then connected to probe card or socket head via pogo blocks or other type of connector. Too many junctions (such as impedance discontinuity) are introduced. This kind of combination not only degrades DUT (Device Under Testing) running speed but also adds more loading of inputs and outputs.

ATE providers submit an improvement way subsequently called Direct docking which integrated the probe card PCB with Probe interface board in one level, similar to a high performance Load board applied on package testing. Both of the scenarios of F/T (final testing) and C/P (circuit probing) with same paces as below: 1)Test Head/ PE cards; 2) Docking of Prober (Handler); 3) Probe interface board (Load board); 4) Probe head (Socket); 5) Probe community (Pin group); and 6) Die/wafer (Package).

In general, scan tests performed by existing ATE systems take place at a slow speed, normally with a 10 MHz-100 MHz clock rate. The loose timing requirements imposed by these systems have an adverse effect on the overall speed of the testing protocol, and even on the accuracy of the results. In order to achieve scan test results that keep up with production demands, the solution is to increase ATE resources, such as increasing the scan band width, or simply to reconstruct the existing ATE overall system structure with one that has more resource capabilities for the implementation of the scan test. This approach unduly increases the cost of the test system and drives up the cost of production.

It is therefore there is a need of testing equipment capable of providing a solution for Semiconductor device testing at wafer level stage with most high speed demanding and lower the usage of interconnectors in-between the test head, probe interface board (HiFix), pogo card (tower) and probe card PCB.

### SUMMARY OF THE INVENTION

The present invention is directed to a semiconductor device testing at wafer level stage, and more particular to a method and an apparatus of stand along muti-cell probe card with high speed testing capability, and with the low cost (having minimum ICs, components modules and power consumption), high speed (with shortest paths) and high throughput (with high parallel count of DUT (Device Under Testing)).

In one embodiment of the invention, a probe card comprising a printed circuit board with at least two connection arrangements thereon and a daughter board connecting to the printed circuit board through one of the connection arrangements is provided. The daughter board comprises a plurality of cell modules, each cell modules has a socket for receiving a device under test, wherein each of the connection arrangements of the printed circuit board is for connecting each of predetermined daughter boards respectively.

In another embodiment of the invention, a probe card comprising a printed circuit board with a plurality of connection arrangements thereon and a daughter board connecting to the printed circuit board through one of the connection arrangements is provided. The daughter board comprises a plurality of cell modules, each cell modules has a socket for receiving a device under test, a plurality of circuit boards with vertically attached on the daughter board surrounding the socket, each the circuit board has a memory unit and a power unit thereon. Each of the connection arrangements of the printed circuit board is for connecting each of predetermined daughter boards respectively.

In still another embodiment of the invention, auto test equipment comprises a test head with a probe card is provided. The probe card comprises a printed circuit board with at least two connection arrangements thereon and a daughter board connecting to the printed circuit board through one of the connection arrangements. The daughter board comprises a plurality of cell modules, each cell modules has a socket for receiving a device under test, wherein each of the connection arrangements of the printed circuit board is for connecting each of predetermined daughter boards respectively.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 shows an exploded view of a probe card according to one embodiment of the present invention;

FIG. 2 shows an exploded view of a probe card according to another embodiment of the present invention;

FIG. 3 shows an exploded view of a probe card according to another embodiment of the present invention;

FIG. 4 shows a top view of a printed circuit board according to one embodiment of the present invention; and

FIG. 5 shows a top view of a subsidiary board according to one embodiment of the present invention.

FIG. 6 is a schematic diagram showing the internal assembly according to an embodiment of the present invention;

FIG. 7 is a schematic diagram showing the inner of the subsidiary board according to the present invention;

FIG. 8 is a schematic cross sectional view of the cell module and the subsidiary board of the present invention;

FIG. 9 is an enlarged view of cross sectional view of the cell module, especially showing the FPGA socket of the cell module of the present invention;

FIG. 10 shows an embodiment of the cell module which is 3 by 3 arrangement;

FIG. 11 shows the embodiment of the cell module which is 3 by 3 arrangement in detail;

FIG. 12 shows another embodiment of the cell module which is 4 by 4 arrangement in detail;

FIG. 13 depicts a schematic cross sectional view of the assembly of the present invention when the each FPGA is received in the FPGA socket for testing the DUT;

### DESCRIPTION OF THE PREFERRED EMBODIMENT

The detailed explanation of the present invention is described as follows. The described preferred embodiments are presented for purposes of illustrations and description, and they are not intended to limit the scope of the present invention.

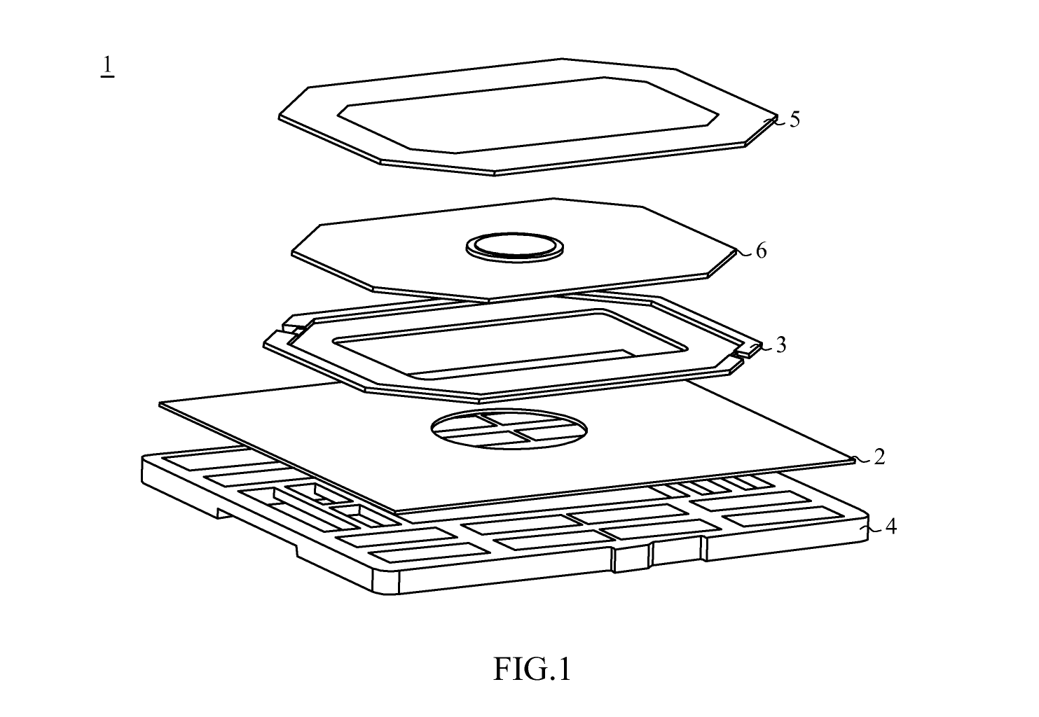

FIG. 1 shows an exploded view of a probe card according to one embodiment of the present invention. The probe card 1 comprises a printed circuit board 2, a sub frame 3, a stiffener 4, a subsidiary or daughter frame 5 and a subsidiary or daughter board 6. As shown in FIG. 1, the daughter board 6 is mounted on the printed circuit board 2. The daughter board 6 is supported on and connected to the printed circuit board 2 through the sub frame 3—and connectors which include conductive pathways that will be further discussed hereinafter. The printed circuit board 2 has at least two connection arrangements each with a plurality of various connectors and sockets suitable and corresponding to at least two various subsidiary or daughter board respectively which will be further described in the following embodiments. The printed circuit board 2 is mounted on the stiffener 4. The daughter frame 5 is mounted on the daughter board 6. The details of the printed circuit board 2, the sub frame 3, the stiffener 4, the subsidiary or daughter frame 5 and the subsidiary or daughter board 6 will be further described hereinafter.

The sub frame 3 and the stiffener 4 may be coupled to the printed circuit board 2 via a fastener system. The fastener system may include for example a plurality of bolts and springs, screws or any other device to provide a relatively constant pressure over a suitable compliance range. The subsidiary or daughter frame 5 can also be coupled to the subsidiary or daughter board 6 via a similar or the same fastener system. The subsidiary or daughter board 6 may also be coupled to the printed circuit board 2 via a similar or the same fastener system.

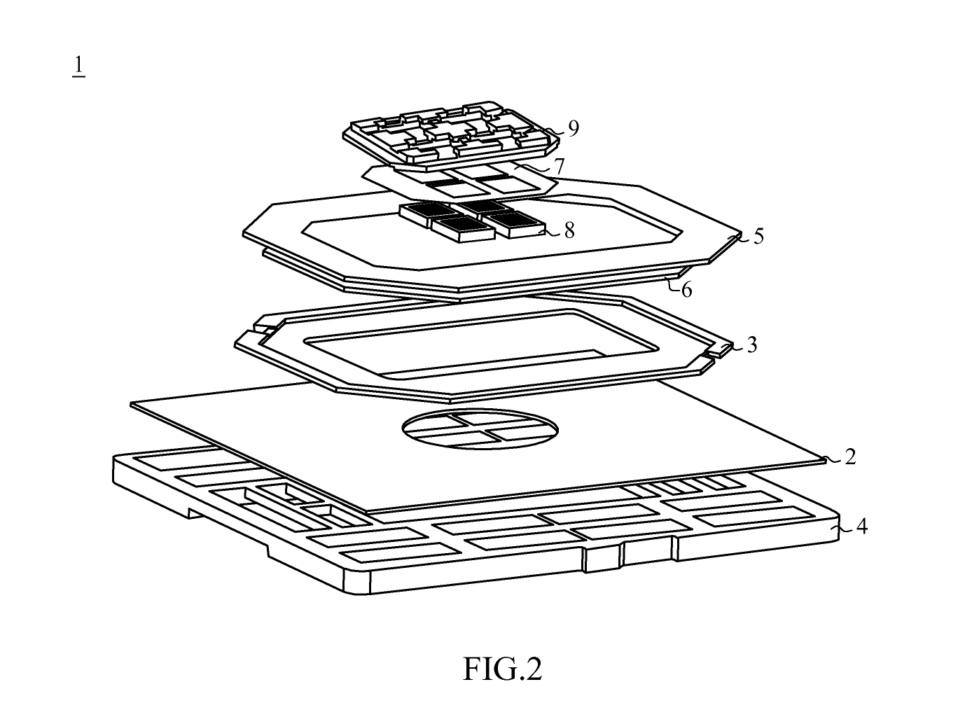

FIG. 2 shows an exploded view of a probe card according to another embodiment of the present invention. In this embodiment, the subsidiary or daughter board 6 comprises sockets or connectors 8 for adapting device under test (DUT). Moreover, a frame 7 and a stiffener 9 are mounted on the daughter board 6. It is noted that the number of the sockets for adapting DUT is not limited. It is also noted that the type of the sockets or connectors as well as DUT is not limited either. In this embodiment, the printed circuit board 2 has one connection arrangement with a plurality of connectors and sockets suitable and corresponding to the subsidiary or daughter board 6 with sockets or connectors 8 for adapting corresponding DUT. The printed circuit board 2 also has other connection arrangements with a plurality of connectors and sockets suitable and corresponding to other subsidiary or daughter boards. The frame 7 and the stiffener 9 can be coupled to the subsidiary or daughter board 6 via a similar or the same fastener system used between the sub frame 3, the stiffener 4 and the printed circuit board 2

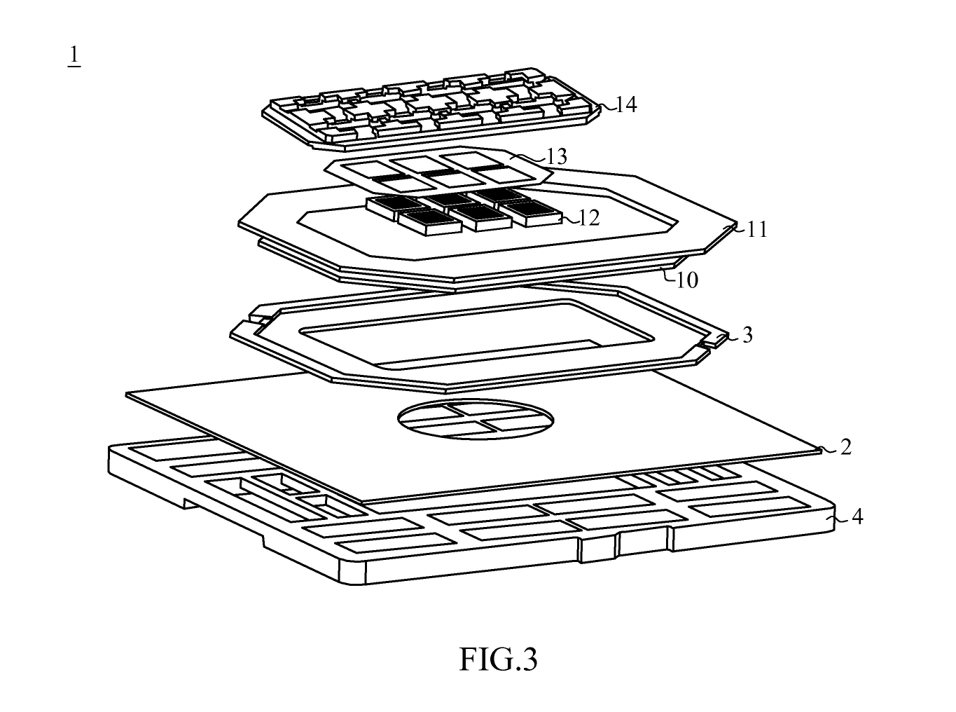

FIG. 3 shows an exploded view of a probe card according to still another embodiment of the present invention. In this embodiment, the subsidiary or daughter board 10 comprises 8 sockets or connectors 12 for adapting DUT. Moreover, a frame 13 and a stiffener 14 suitable and corresponding to the daughter board 10 and the sockets or connectors 12 are mounted on the daughter board 10. A daughter frame 11 is mounted on the daughter board 10. It is noted that the number of the sockets 12 for adapting DUT is not limited to 8. It is also noted that the type of the sockets or connectors 12 as well as DUT is not limited either. In this embodiment, connectors and sockets on the printed circuit board 2 suitable and corresponding to the subsidiary or daughter board 10 with sockets or connectors 12 for adapting corresponding DUT are used to connect the subsidiary or daughter board 10. The frame 13 and the stiffener 14 can be coupled to the subsidiary or daughter board 10 via a similar or the same fastener system used between the sub frame 3, the stiffener 4 and the printed circuit board 2.

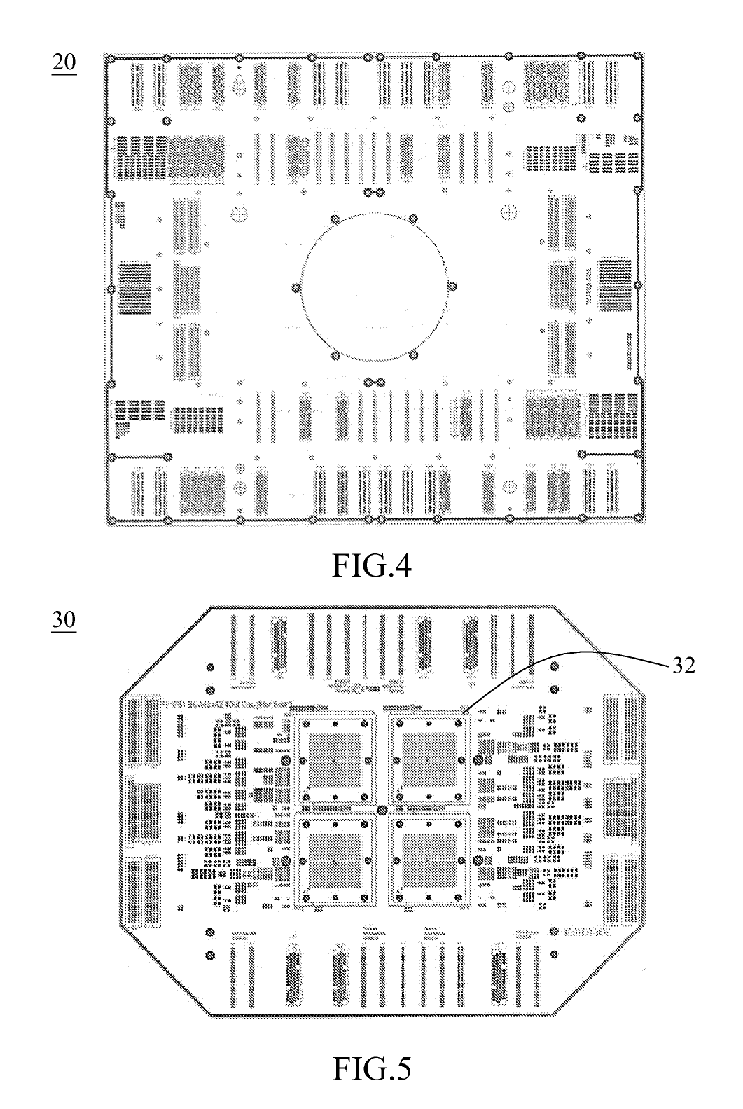

FIG. 4 shows a top view or a tester side view of a printed circuit board according to one embodiment of the present invention. As shown in FIG. 4, the printed circuit board 20 has connection arrangements with a plurality of sockets or connectors suitable and corresponding to various subsidiary or daughter board. It is noted that the connection arrangements on the printed circuit board 20 shown in FIG. 4 are only example, not a limitation. The number, type and arrangement of the sockets or connectors on the printed circuit board 20 can be chose base on various designs, testing requirements, as well as types of DUT. It is also noted that the printed circuit board 20 is designed for adapting various subsidiary or daughter board for various testing requirements.

FIG. 5 shows a top view or a tester side view of a subsidiary or daughter board according to one embodiment of the present invention. As shown in FIG. 5, in this embodiment, the subsidiary or daughter board 30 comprises sockets or connectors 32 thereon for adapting 4 DUTs. The subsidiary or daughter board 30 has a plurality of connectors contact pads, pin contacts or sockets corresponding to their counterparts on the printed circuit board 20 so as to achieve connections and circuit paths between the daughter board 30 and the printed circuit board 20. It is noted that the type, number, and arrangement of the connectors contact pads, pin contacts or sockets on the daughter board 30 are only examples, not limitations. The number, type and arrangement of the connectors contact pads, pin contacts or sockets on the daughter board 30 can be chose base on various designs, testing requirements, as well as types of DUT for any one with ordinary skill in the art.

Lastly, the most updated FPGA device chip was introduced, which IO speed could be approaching to 1800+ Mbps, which accurate delay lines could be applied for AC testing, and the variable Vcco and Vref could be applied for VIH/VIL and VOH/VOL testing, and the extra monitor circuits could be applied for power current testing. With this device chip size 45*45 mm, it can be integrated on above pace (3) Probe interface board directly.

Optimize the test channel deployment and the necessary peripheral circuitries design then mapping the Hard docking plate of Prober to the Stiffener design of pace (3), we can dedicate this Probe interface board for multi probe heads mounting, then we called it as standalone multi-cell probe card, we could locate it on the posts of prober (replace the existed docking plate/ring carrier/card holder) to form an enclosed chamber for wafer probing test.

The main problems of previous conventional ATE with the handler/prober are described as too many junctions, in this section will outline the summaries, and show how them involved from studying the previous problems.

First of all, high speed transmission lines need be well controlled to meet 50 ohm and the signal paths should be shorter than the one tenth of the wave-length of desired bandwidth (e.g., 1600 Mbps, 800 MHz, wavelength 374.74 mm). We selected the proper laminate materials from 2 to 4.5 dielectricity to build up the real interface circuits, we will have the target of the signal trace as 18.787 mm around, this brought us the scale to set up a new testing interface. Secondary, in order to provide the optimized throughput for production test of DUT, we have to offer digital channel enough for multi-DUTs in parallel without sharing and switching. One FPGA device we selected is capable of covering the channels of 8 DDR3 DUTs. By putting configuration; flash; power module and external memory connectors, then link the probe head with a well designed space transformer, we will have a completed FPGA testing cell. Duplicate & planting the cells as grid array on a subsidiary or daughter board or a probe interface board (PIB) as the wafer size demanding, there will be a multi-cell probe card.

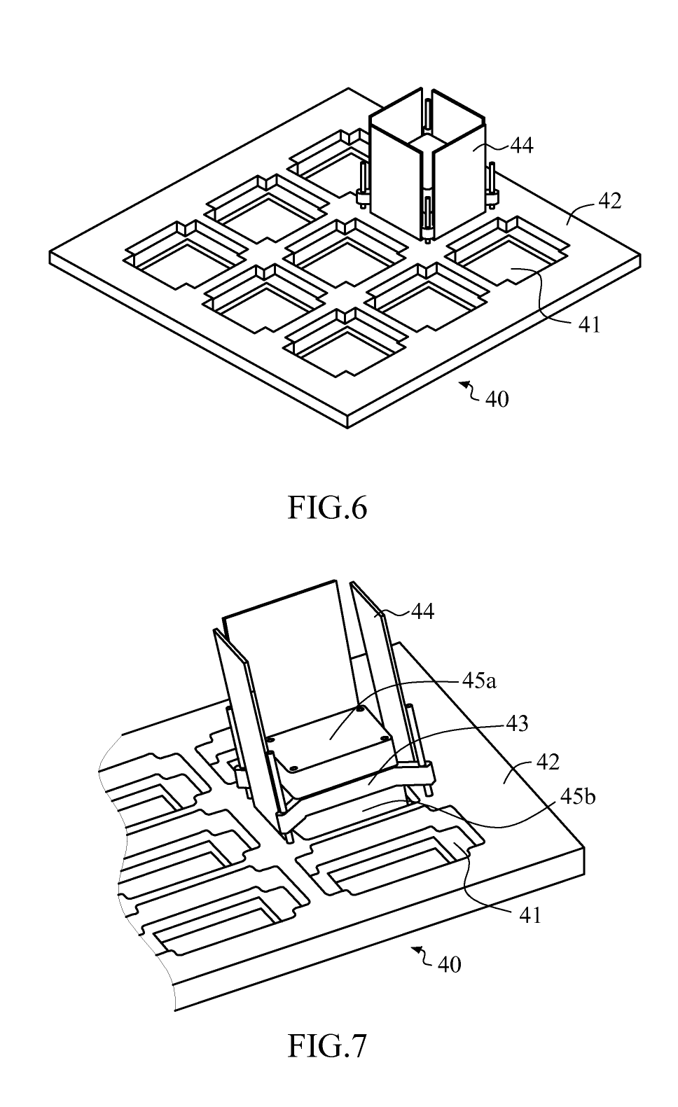

FIG. 6 shows a schematic diagram showing the internal assembly according to an embodiment of the present invention. A printed circuit card (PCB) 40 having a grid array with 9 test cells on a subsidiary or daughter board or a PIB 41 is shown. Four circuit boards 44 with memory units and power units vertically attached on the subsidiary or daughter board 41 as well as a stiffener 42 are also shown in FIG. 6. The details of the circuit boards 44 with memory units and power units will be further described hereinafter.

FIG. 7 shows a schematic diagram showing the inner of the subsidiary board according to the present invention. As shown in FIG. 7, cooling components 45a and 45b as well as a mounting component 43 are attached on each test cell of the subsidiary or daughter board 41. The mounting component 43 is used to secure the cooling components 45a and 45b above a DUT attached on the socket of the subsidiary or daughter board 41. In this embodiment, the mounting component 43 also assists the vertical attachment of the circuit boards 44 on the subsidiary or daughter board 41. A cell module including a DUT, a socket with the DUT attached on, the circuit boards 44, the cooling components 45a and 45b and the mounting component 43 is thus formed and will be further described in detail hereinafter.

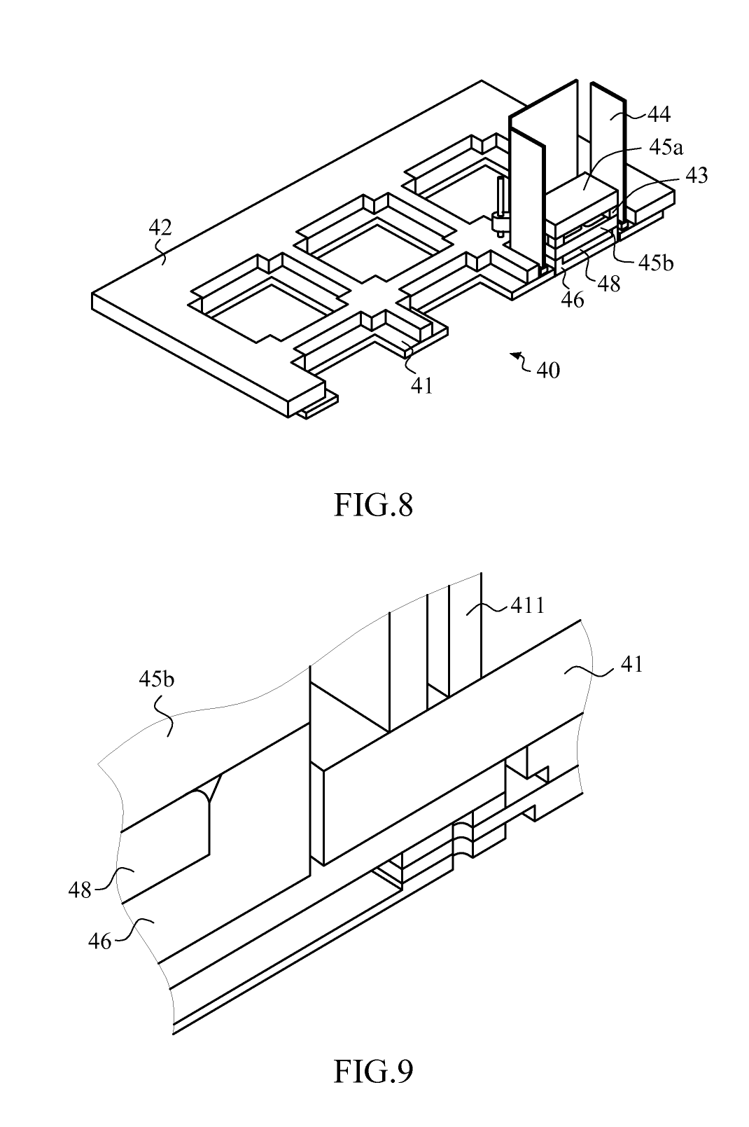

FIG. 8 is a schematic cross sectional view of the cell module and the subsidiary board of the present invention. As shown in FIG. 8, the cooling components 45a and 45b are attached on a DUT 48 and a socket 46 on the subsidiary or daughter board 41 through the mounting component 43. Also shown in FIG. 8, the circuit boards 44 with memory units and power units are vertically attached on connectors surrounding the DUT 48 and the socket 46 on the subsidiary or daughter board 41. In this configuration, when each DUT 48 is attached on the socket 46, the signal trace from the DUT 48 to the PCB 40 via the subsidiary board 41 would be significantly shortened. It is capable for operating high speed testing. In this embodiment, the DUT 48 and the socket 46 comprise, but not limited to, a FPGA DUT and a FPGA socket.

FIG. 9 is an enlarged view of cross sectional view of the cell module, especially showing the socket of the cell module of the present invention. As shown in FIG. 9, a connector 411 for receiving the circuit board 44 is on the subsidiary or daughter board 41 to form a circuit path between the memory units, the power units on the circuit board 44 and the. subsidiary or daughter board 41 Also shown in FIG. 9, the cooling component 45b is attached on the DUT 48 and the socket 46.

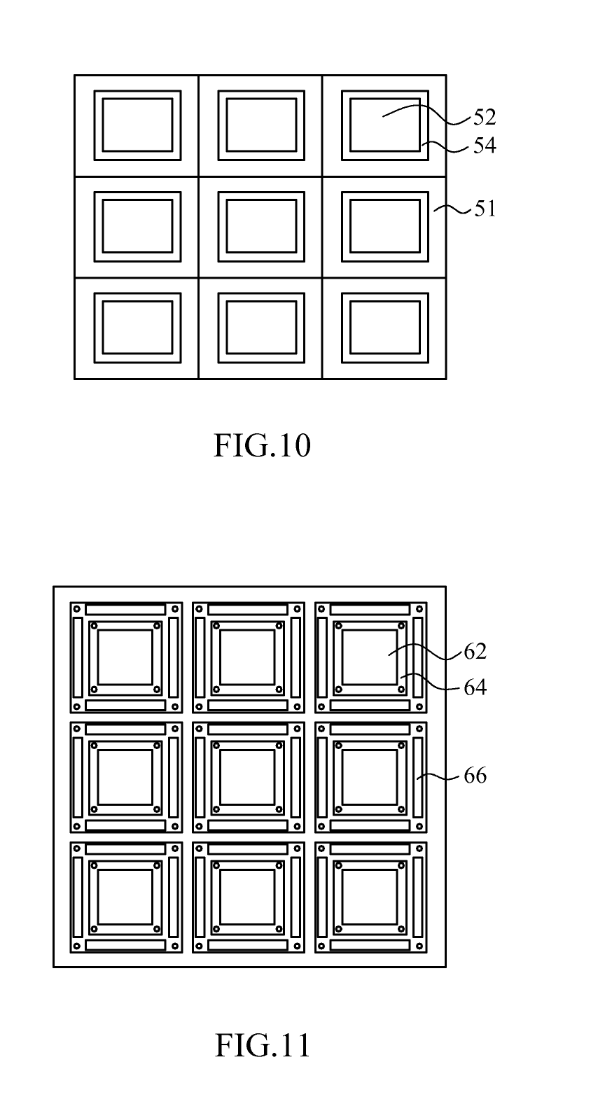

FIG. 10 shows an embodiment of the cell module which is 3 by 3 arrangement. Each test cell comprises a DUT 52 and a socket 54 on a subsidiary or daughter board 51. The test cell may further comprises surrounding and vertically attached circuit boards with memory units and power units thereon as well as cooling components on the DUT 52 and the socket 54 which are not shown in this top view diagram for high speed testing.

FIG. 11 shows the embodiment of the cell module which is 3 by 3 arrangement in detail. In this embodiment, each FPGA DUT 62 is attached on a FPGA socket 64 with four surrounding connectors 66 for receiving vertically attached circuit boards with memory units and power units (not shown) thereon. Each test cell may further comprises cooling components on the FPGA DUT 62 and the FPGA socket 64 which are not shown in this top view diagram.

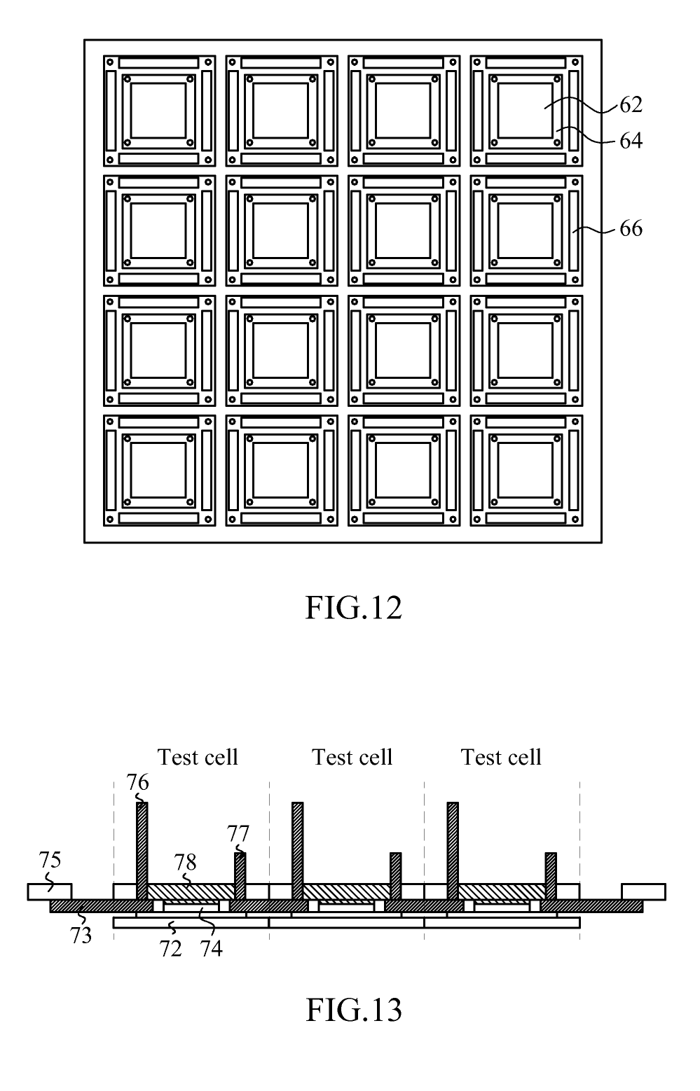

FIG. 12 shows another embodiment of the cell module which is 4 by 4 arrangement in detail. In this embodiment, a total of 16 cell modules are shown, and each FPGA DUT 62 is attached on a FPGA socket 64 with four surrounding connectors 66 for receiving vertically attached circuit boards with memory units and power units (not shown) thereon. Each test cell may further comprises cooling components on the FPGA DUT 62 and the FPGA socket 64 which are not shown in this top view diagram.

FIG. 13 shows a schematic cross sectional view of the assembly of a probe card of the present invention. As shown in FIG. 13, in one embodiment, a probe card comprises a printed circuit board 72, a subsidiary or daughter board or a probe interface board 73 with a plurality of cell modules thereon and a stiffener 75. Each cell module comprises a socket 74 for receiving a DUT, a cooling unit 78 on the socket 74, and vertically attached circuit boards with memory units and power units surrounding the socket 74 and on the subsidiary or daughter board or the probe interface board 73. In this embodiment, the DUT and the socket 74 comprise, but not limited to, a FPGA DUT and a FPGA socket.

The probe card of the invention can be applied to auto test equipment (ATE). The ATE may comprise a test Head/PE cards and a handler, and the probe card is mounted on and connected to the test head. The cell modules of the probe card can be referred as a probe head. The direct docking which integrate the PCB of a probe card with a subsidiary or daughter board or a probe interface board in one level is capable for high speed testing.

When the each FPGA DUT is received in the FPGA socket, the signal trace from the DUT to the printed circuit board via each stand alone subsidiary or daughter board would be significantly shortened. In this case, it is capable for operating high speed testing. Besides, each stand along subsidiary or daughter board also comprises vertically attached circuit boards with respective memory unit and power unit. The memory unit and power unit is vertically attached in order to save space of circuitry arrangement.

The muti-cell probe card of the invention has advantages of high speed testing capability, low cost (having minimum ICs, components modules and power consumption), high speed (with shortest paths) and high throughput (with high parallel count of DUT). Furthermore, the probe card of the invention comprises a printed circuit board which is compatible to various replaceable subsidiary or daughter boards. The printed circuit board comprises a plurality of connectors contact pads, pin contacts or sockets corresponding to their counterparts on various replaceable subsidiary or daughter boards.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A probe card comprising:
a printed circuit board with at least two connection arrangements thereon; and
a daughter board connecting to the printed circuit board through one of the connection arrangements, the daughter board comprising a plurality of cell modules, each cell modules having a socket for receiving a device under test;
wherein each of the connection arrangements of the printed circuit board is for connecting each of predetermined daughter boards respectively.

2. The probe card according to claim 1, wherein the socket and the device under test comprise a field programming grid array (FPGA) socket and a FPGA device under test.

3. The probe card according to claim 1, wherein the cell module further comprises four circuit boards vertically attached on the daughter board surrounding the socket.

4. The probe card according to claim 3, wherein each the circuit board has a memory unit and a power unit thereon.

5. The probe card according to claim 1, wherein the cell module further comprises a cooling unit on the socket.

6. The probe card according to claim 1, further comprising a stiffener on which the printed circuit board is mounted.

7. The probe card according to claim 1, further comprising a sub frame, wherein the daughter board is supported on and connected to the printed circuit board via the sub frame.

8. The probe card according to claim 1, further comprising a daughter frame mounted on the daughter board.

9. The probe card according to claim 1, further comprising a frame and a stiffener mounted on the daughter board.

10. A probe card comprising:
a printed circuit board with a plurality of connection arrangements thereon; and
a daughter board connecting to the printed circuit board through one of the connection arrangements, the daughter board comprising a plurality of cell modules, each cell modules having a socket for receiving a device under test, a plurality of circuit boards with vertically attached on the daughter board surrounding the socket, each the circuit board having a memory unit and a power unit thereon;
wherein each of the connection arrangements of the printed circuit board is for connecting each of predetermined daughter boards respectively.

11. The probe card according to claim 10, wherein the socket and the device under test comprise a FPGA socket and a FPGA device under test.

12. The probe card according to claim 10, wherein the cell module further comprises a cooling unit on the socket.

13. The probe card according to claim 10, further comprising a stiffener on which the printed circuit board is mounted.

14. The probe card according to claim 10, further comprising a sub frame, wherein the daughter board is supported on and connected to the printed circuit board via the sub frame.

15. The probe card according to claim 10, further comprising a daughter frame mounted on the daughter board.

16. The probe card according to claim 10, further comprising a frame and a stiffener mounted on the daughter board.

17. Auto test equipment, comprising:
a test head with a probe card, the probe card comprising:
a printed circuit board with at least two connection arrangements thereon; and
a daughter board connecting to the printed circuit board through one of the connection arrangements, the daughter board comprising a plurality of cell modules, each cell modules having a socket for receiving a device under test;
wherein each of the connection arrangements of the printed circuit board is for connecting each of predetermined daughter boards respectively.

18. The auto test equipment according to claim 17, wherein the socket and the device under test comprise a FPGA socket and a FPGA device under test.

19. The auto test equipment according to claim 17, wherein the cell module further comprises four circuit boards vertically attached on the daughter board surrounding the socket.

20. The auto test equipment according to claim 19, wherein each the circuit board has a memory unit and a power unit thereon.

21. The auto test equipment according to claim 17, wherein the cell module further comprises a cooling unit on the socket.

22. The auto test equipment according to claim 17, wherein the cell module is a 3 by 3 matrix or a 4 by 4 matrix for containing the devices under test.
